(19) United States
(12) Patent Application Publication
(10) Pub. No.: US 2025/0255129 A1
(43) Pub. Date: Aug. 7, 2025

(54) ARRAY SUBSTRATE AND DISPLAY PANEL

(71) Applicants: Hefei Visionox Technology Co., Ltd., Hefei (CN); KunShan Go-Visionox Opto-Electronics Co., Ltd., Kunshan (CN)

(72) Inventors: Yang HE, Hefei (CN); Xiujian ZHU, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 19/189,175

(22) Filed: Apr. 24, 2025

Related U.S. Application Data
(63) Continuation of application No. PCT/CN2023/077237, filed on Feb. 20, 2023.

(30) Foreign Application Priority Data
Nov. 3, 2022 (CN) 202211371395.7

(51) Int. Cl. H10K 59/131

(52) U.S. Cl. CPC H10K 59/131

(57) ABSTRACT

Provided are an array substrate and a display panel. The array substrate includes: a substrate (01); a first conductive layer (02), the first conductive layer (02) including a first power line (210); and a second conductive layer (03), the second conductive layer (03) including at least one first signal line (310) and at least one second signal line (320) spaced apart in a first direction (X) and at least one second power line (330) between the first signal line (310) and the second signal line (320), where the first power line (210), the first signal line (310), the second signal line (320) and the second power line (330) are each formed as extending in a second direction (Y), and the first power line (210) and the second power line (330) are connected through via holes.

### CROSS-REFERENCE TO RELATED APPLICATIONS

This application is a continuation application of International Application No. PCT/CN 2023/077237, filed on Feb. 20, 2023, which claims priority to Chinese Patent Application No. 202211371395.7, filed on Nov. 3, 2022, the entire content of which is incorporated herein by reference.

### FIELD

The present application relates to the field of display, and in particular to an array substrate and a display panel.

### BACKGROUND

An organic light-emitting diode (OLED) is an active light-emitting device. Compared with a conventional liquid crystal display (LCD) method, an OLED display technology does not require a backlight and has a self-luminescence characteristic. The OLED uses a thin film layer of an organic material and a glass substrate. When a current passes through the film layer of the organic material, the organic material emits light. Therefore, an OLED display panel can significantly save power, can be made lighter and thinner, withstands a wider range of temperature changes than an LCD display panel, and has a larger viewing angle. The OLED display panel is expected to become the next generation of flat panel display technology after LCD, and is currently one of the flat panel display technologies that have attracted most attention.

The OLED display panel includes an array substrate and a display substrate. The array substrate includes power lines and pixel circuits. The power lines send drive signals to the pixel circuits such that the pixel circuits drive the display substrate to emit light. Excessive resistance of the power line may lead to insufficient drive voltage, which affects the display effect of the display panel.

### SUMMARY

Embodiments of the present application provide an array substrate and a display panel, with the aim of improving the display effect of the display panel.

An embodiment of a first aspect of the present application provides an array substrate, the array substrate including: a substrate; a first conductive layer located on one side of the substrate, the first conductive layer including a first power line; and a second conductive layer located on a side of the first conductive layer facing away from the substrate, the second conductive layer including at least one first signal line and at least one second signal line spaced apart in a first direction and at least one second power line between the first signal line and the second signal line, where the first power line, the first signal line, the second signal line and the second power line are each formed as extending in a second direction, and the first power line and the second power line are connected through via holes.

An embodiment of a second aspect of the present application provides a display panel including an array substrate according to any one of the above-described embodiments of the first aspect.

The array substrate according to the embodiment of the present application includes a substrate and a first conductive layer and a second conductive layer disposed on the substrate. A first power line is disposed in the first conductive layer, and at least one first signal line and at least one second signal line and at least one second power line between the first signal line and the second signal line are disposed in the second conductive layer. The first power line and the second power line are connected through the via holes, which can increase the distribution area of the power lines, thus reducing the resistance of the power lines, mitigating the impact of insufficient drive voltage on the display panel, and improving the display effect of the display panel. In addition, the second conductive layer is further provided with at least one first signal line and at least one second signal line that are disposed side by side with the at least one second power line in the first direction, which can enrich the functions of the second conductive layer.

### BRIEF DESCRIPTION OF THE DRAWINGS

FIG. 1 is a top view of an array substrate according to an embodiment of the present application;

FIG. 2 is a partial sectional view of FIG. 1;

FIG. 3 is a top view of an array substrate according to a further embodiment of the present application;

FIG. 4 is a schematic structural diagram of a pixel circuit of an array substrate according to an embodiment of the present application; and

FIG. 5 is a structural schematic partial enlarged view of FIG. 1.

### DETAILED DESCRIPTION OF THE EMBODIMENTS

In the description of the structure of a component, a layer or region referred as being located “above” or “over” another layer or region may be directly on the other layer or region, or there may be other layers or regions between it and the other layer or region. Moreover, if the component is turned over, the layer or region will be located “below” or “under” the other layer or region.

Embodiments of the present application provide an array substrate and a preparation method therefor. Various embodiments of the array substrate and the preparation method therefor will be described below with reference to the accompanying drawings.

An embodiment of the present application provides an array substrate that may be used in a display panel. The display panel may be an organic light-emitting diode (OLED) display panel.

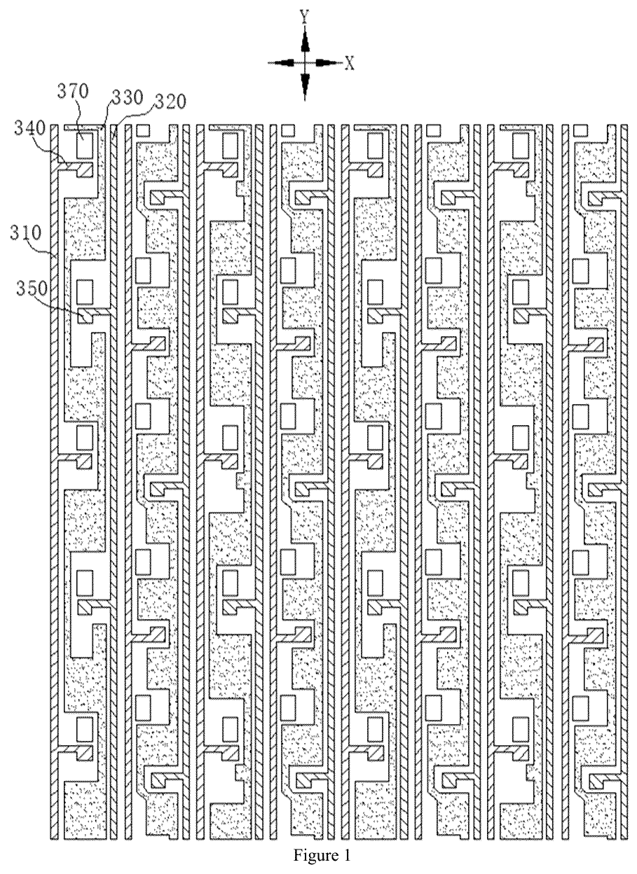

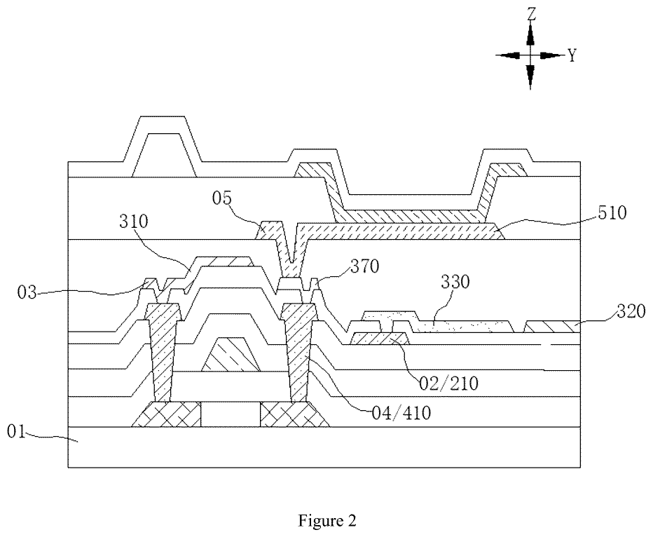

With reference to FIGS. 1 and 2, FIG. 1 shows a top view of a layered structure of an array substrate according to an embodiment of the present application, and FIG. 2 is a partial sectional view of FIG. 1.

As shown in FIGS. 1 and 2, an embodiment of a first aspect of the present application provides an array substrate. The array substrate includes a substrate 01, a first conductive layer 02, and a second conductive layer 03, where the first conductive layer 02 is located on one side of the substrate 01, and the first conductive layer 02 includes a first power line 210; and the second conductive layer 03 is located on a side of the first conductive layer 02 facing away from the substrate 01, the second conductive layer 03 includes at least one first signal line 310 and at least one second signal line 320 spaced apart in a first direction X and at least one second power line 330 between the first signal line 310 and the second signal line 320, where the first power line 210, the first signal line 310, the second signal line 320 and the second power line 330 are each formed as extending in a second direction Y, and the first power line 210 and the second power line 330 are connected through via holes.

The array substrate according to the embodiment of the present application includes the substrate 01 and the first conductive layer 02 and the second conductive layer 03 disposed on the substrate 01. The first power line 210 is disposed in the first conductive layer 02, and the first signal line 310, the second signal line 320 and the second power line 330 between the first signal line 310 and the second signal line 320 are disposed in the second conductive layer 03. The first power line 210 and the second power line 330 are connected through the via holes, which can increase the distribution area of the power lines, thus reducing the resistance of the power lines, mitigating the impact of insufficient drive voltage on the display panel, and then improving the display effect of the display panel. In addition, the second conductive layer 03 is further provided with the first signal line 310 and the second signal line 320 that are disposed side by side with the second power line 330 in the first direction X, which can enrich the functions of the second conductive layer 03.

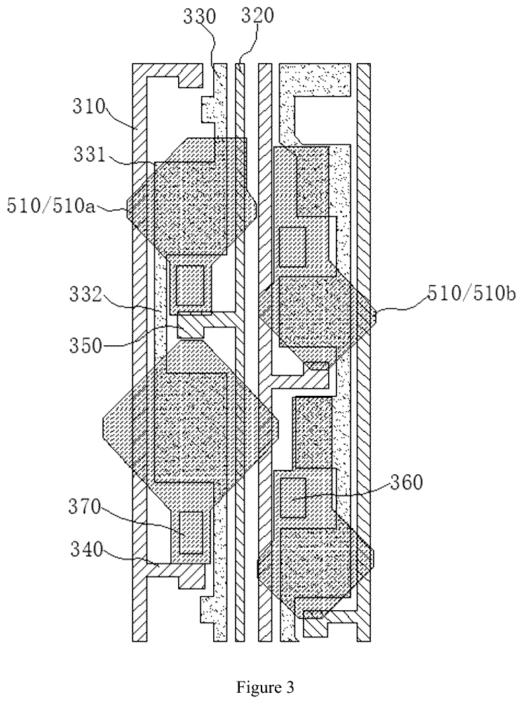

With reference to FIGS. 1 to 3 together, FIG. 3 is a structural schematic enlarged view of an array substrate according to a further embodiment of the present application, and FIG. 3 differs from FIG. 1 in that a conductive layer including pixel electrodes 510 is added in the array substrate.

In one embodiment, a display panel includes an array substrate and a light-emitting layer on the array substrate, where the light-emitting layer includes a hole injection layer, a hole transport layer, a light-emitting material layer, an electron transport layer, and an electron injection layer laminated in sequence. The pixel electrodes 510 may each be a positive or negative electrode.

The second power line 330 is located between the first signal line 310 and the second signal line 320, and an orthographic projection of the second power line 330 in a thickness direction Z of the array substrate overlaps an orthographic projection of each of the pixel electrodes 510 located thereon in the thickness direction Z of the array substrate. Thus, by adjusting the shape of the second power line 330, the flatness of the pixel electrodes 510 may be improved to alleviate the problem of color deviation due to the reflection of light emitted from the light-emitting layer by the pixel electrodes 510 in various directions, thus better improving the display effect of the display panel.

In one embodiment, an insulation layer is provided between the first conductive layer 02 and the second conductive layer 03 to prevent a short-circuit connection between traces in the first conductive layer 02 and the second conductive layer 03. In the embodiment of the present application, the insulation layer is disposed between two adjacent conductive layers to prevent the short-circuit connection, which will not be repeated herein.

The substrate 01 may be a flexible substrate or a rigid substrate. For example, a material of the substrate 01 may include a flexible material such as polyimide; in one embodiment, the material of the substrate 01 may include a rigid material such as glass. Further film layers may be provided between the first conductive layer 02 and the substrate 01, as long as the first conductive layer 02 is located on one side of the substrate 01. A material of the first conductive layer 02 may include a metallic material such that the first power line 210 has good conductivity. A material of the second conductive layer 03 may include a metallic material such that the first signal line 310, the second signal line 320, and the second power line 330 have good conductivity.

The first signal line 310 and the second signal line 320 are provided in various configurations. In some embodiments, the first signal line 310 is a first data line and the second signal line 320 is a second data line. The array substrate further includes a plurality of pixel circuits disposed on one side of the substrate 01. The plurality of pixel circuits are arranged in an array in the first direction X and the second direction Y. The second direction Y is a column direction. The first data line and the second data line are used to provide data signals to the plurality of pixel circuits arranged in the same column in the second direction Y.

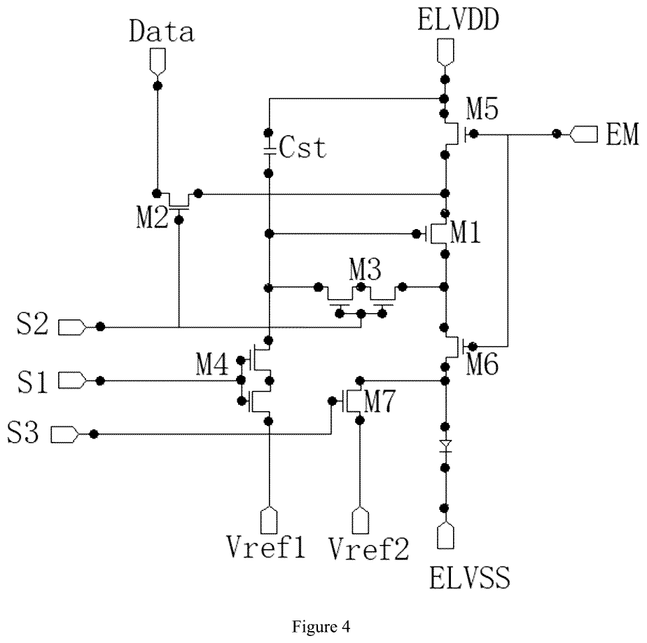

As shown in FIG. 4, a data line data is configured to send a data signal to a pixel circuit. In one embodiment, the first data line provides a data signal to one of two adjacent pixel circuits in the same column, and the second data line provides a data signal to the other one of the two adjacent pixel circuits. Then, the number of pixel circuits to be driven by the same data line is reduced, which can reduce the time for transmitting the data signal on the data signal line, reduce the delay, and improve the power supply time of a single sub-pixel.

In these embodiments, data signals may be transmitted to the plurality of pixel circuits in the same column by the first data line and the second data line, which can prolong the charging time of a single pixel circuit and improve the display effect of the display panel.

In some embodiments, the array substrate further includes a fourth conductive layer 05. The fourth conductive layer 05 is located on a side of the second conductive layer 03 facing away from the substrate 01. The fourth conductive layer 05 includes pixel electrodes 510.

The first data line and the second data line are disposed corresponding to the same column of pixel circuits, then the first data line and the second data line may be disposed corresponding to the same column of pixel electrodes 510, and an orthographic projection of the second power line 330 between the first data line and the second data line in the thickness direction Z at least partially overlaps an orthographic projection of each pixel electrode 510 in the thickness direction Z. The distribution of the second power line 330 affects the surface shape of the insulation layer located thereon, which further affects the flatness of the pixel electrode 510. Therefore, the flatness of the pixel electrode 510 can be improved by a reasonable distribution of the second power line 330, which is conducive to improving the display effect. For example, with the flatness of the pixel electrode 510 improved, the display effect of the display panel that is affected by excessively dispersive light that is emitted from the light-emitting layer and is reflected by the pixel electrode 510 due to poor flatness of the pixel electrode 510 may be improved.

In these embodiments, the second conductive layer 03 is closer to the fourth conductive layer 05. For example, in the process of preparing the pixel electrode 510 after the insulation layer is prepared on the second conductive layer 03, the flatness of a surface of the second conductive layer 03 facing toward the insulation layer will affect the flatness of a surface of the pixel electrode 510 on the insulation layer. Moreover, the distribution of the first signal line 310, the second signal line 320 and the second power line 330 will also affect the flatness of the surface of the insulation layer, and accordingly, the distribution of the first signal line 310, the second signal line 320 and the second power line 330 will indirectly affect the flatness of the pixel electrode 510. The orthographic projections of the pixel electrode 510 and the second power line 330 at least partially overlap such that the second power line 330 can alleviate the problem of poor flatness of the pixel electrode 510.

In addition, since the first signal line 310 and the second signal line 320 are disposed within the conductive layer closer to the pixel electrode 510, a distance between the first signal line 310 and the second signal line 320 and other signal lines in the array substrate in the thickness direction Z can be increased, and parasitic circuits generated by the overlapping between the first signal line 310 and the second signal line 320 and the other signal lines can be reduced, thus ensuring the stability of signal transmission.

The second power line 330 is provided in various configurations, and in one embodiment, the second power line 330 may extend in the second direction Y and may have equal width.

In some other embodiments, as shown in FIG. 3, the second power line 330 includes a plurality of power supply blocks 331 spaced apart in the second direction Y and a connecting line 332 connected between every two adjacent power supply blocks 331, where a width of the connecting line 332 in the first direction X is less than a width of one of the power supply blocks 331 in the first direction X.

In these embodiments, the second power line 330 includes the power supply blocks 331 and the connecting line 332. The power supply blocks 331 each have a larger width, which can improve the distribution area of the second power line 330 and reduce the resistance of the second power line 330 to increase the drive voltage, thus improving the display effect of the display panel.

In addition, by reasonably positioning the power supply blocks 331 and the connecting line 332, an orthographic projection of each power supply block 331 in the thickness direction Z of the array substrate may overlap the orthographic projection of the pixel electrode 510 in the thickness direction Z of the array substrate. Since the area of the orthographic projection of the power supply block 331 in the thickness direction Z of the array substrate is large, it can increase the overlapping area between the orthographic projection of the power supply block 331 in the thickness direction Z and the orthographic projection of the pixel electrode 510 in the thickness direction Z. By reasonably setting the shape of the power supply block 331, the flatness of the pixel electrode 510 can be indirectly affected, and accordingly the problem of poor flatness of the pixel electrode 510 can be better alleviated. By reasonably positioning the connecting line 332, the problem of a short-circuit connection between the second power line 330 and the first signal line 310 and the second signal line 320 may also be alleviated.

The shape of the power supply block 331 may be set in various ways, and the orthographic projection of the power supply block 331 on the substrate 01 may be in the shape of a circle, a semicircle, a polygon, or a special shape. In one embodiment, the orthographic projection of the power supply block 331 on the substrate 01 is a quadrilateral shape such as a rectangle, a square, and a rhombus. The shape of the orthographic projection of the power supply block 331 on the substrate 01 is not limited herein, and can be set specifically according to actual needs.

When the second power line 330 includes the connecting line 332 and the power supply blocks 331, the orthographic projection of the connecting line 332 and/or power supply block 331 in the thickness direction Z at least partially overlaps the orthographic projection of the pixel electrode 510 in the thickness direction Z.

In one embodiment, the orthographic projection of one of the power supply blocks 331 in the thickness direction Z at least partially overlaps the orthographic projection of each of the pixel electrodes 510 in the thickness direction Z. The distribution area of the power supply block 331 is larger, and the overlapping between the power supply block 331 and the pixel electrode 510 can better alleviate the problem of poor flatness of the pixel electrode 510.

In one embodiment, the orthographic projection of the power supply block 331 in the thickness direction Z is in central symmetry about a center point of the orthographic projection of the pixel electrode 510 in the thickness direction Z. The center point of the orthographic projection of the pixel electrode 510 in the thickness direction Z may be a geometric center point of the orthographic projection of the pixel electrode 510 in the thickness direction Z. The orthographic projection of the power supply block 331 in the thickness direction Z is in central symmetry about this geometric center point, so that the flatness of different positions around the center of the pixel electrodes 510 is similar, which better overcomes the impact of poor flatness of the pixel electrode 510 on the display effect.

In one embodiment, at least some of the power supply blocks 331 satisfy: the orthographic projection of the power supply block 331 in the thickness direction Z lies in the orthographic projection of the pixel electrode 510 in the thickness direction Z, so that the power supply block 331 can better overcome the impact of poor flatness of the pixel electrode 510 on the display effect.

For example, the center of the orthographic projection of the power supply block 331 in the thickness direction Z overlaps the center of the orthographic projection of the pixel electrode 510 in the thickness direction Z, so that the power supply block 331 can better overcome the impact of poor flatness of the pixel electrode 510 on the display effect.

The array substrate includes a plurality of pixel electrodes 510, and the area of the pixel electrodes 510 may be the same or different. For example, when the array substrate is used for a display panel and the display panel includes a plurality of sub-pixels, the distribution area of the plurality of sub-pixels may be the same or different. For example, in some embodiments, the sub-pixels of the display panel include red sub-pixels, blue sub-pixels, and green sub-pixels. The distribution area of the blue sub-pixels may be large, while the distribution area of the green sub-pixels may be small, and accordingly, the area of an orthographic projection of a pixel electrode 510 of each blue sub-pixel in the thickness direction Z is larger than the area of an orthographic projection of a pixel electrode 510 of each green sub-pixel in the thickness direction Z.

When the area of the orthographic projections of two pixel electrodes 510 in the thickness direction Z is different, the area of the orthographic projections of the power supply blocks 331, corresponding to the two pixel electrodes 510, in the thickness direction Z may be the same or different.

In some embodiments, at least two pixel electrodes 510 have different areas, at least two power supply blocks 331 have different areas, and the area of the power supply blocks 331 is in positive correlation with the area of the pixel electrodes 510 corresponding thereto. For example, the pixel electrode 510 includes a first pixel electrode and a second pixel electrode, and the power supply blocks 331 include a first power supply block and a second power supply block. An orthographic projection of the first power supply block in the thickness direction Z least partially overlaps an orthographic projection of the first pixel electrode in the thickness direction Z, and an orthographic projection of the second power supply block in the thickness direction Z at least partially overlaps the second pixel electrode in the thickness direction Z, that is, the first power supply block corresponds to the first pixel electrode, and the second power supply block corresponds to the second pixel electrode. When the area of the orthographic projection of the first pixel electrode in the thickness direction Z is larger than the area of the orthographic projection of the second pixel electrode in the thickness direction Z, the area of the orthographic projection of the first power supply block in the thickness direction Z is larger than the area of the orthographic projection of the second power supply block in the thickness direction Z.

In these embodiments, the pixel electrodes 510 having different areas correspond to the power supply blocks 331 having different areas, and the area of the power supply blocks 331 is in positive correlation with the area of the pixel electrodes 510 corresponding thereto, which can effectively achieve targeted improvement on the flatness of the pixel electrodes 510 corresponding to the power supply blocks 331, and better improve the display effect of the display panel.

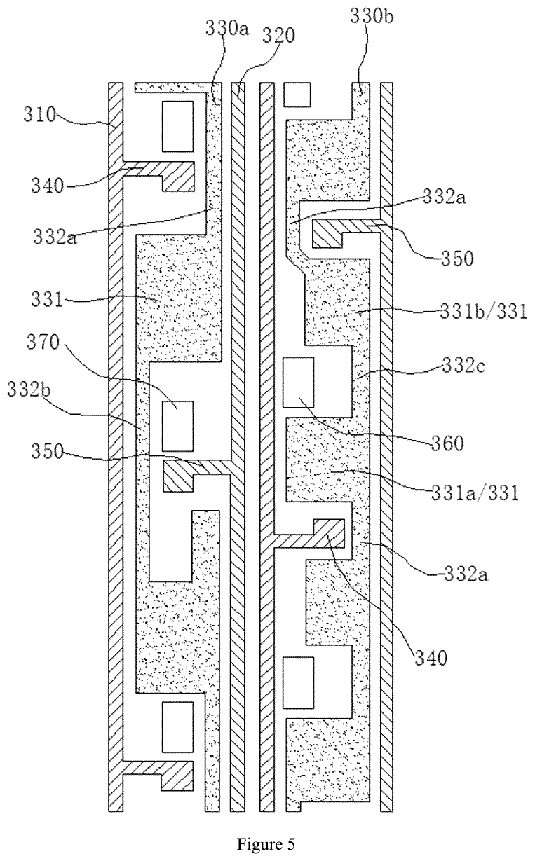

With reference to FIGS. 1 to 5 together, FIG. 5 is a structural schematic partial enlarged view of FIG. 1.

In some embodiments, as shown in FIGS. 1 to 5, the second conductive layer 03 further includes a first connection portion 340 and a second connection portion 350. The first connection portion 340 is connected to the first signal line 310 and located between the first signal line 310 and the second signal line 320. The second connection portion 350 is connected to the second signal line 320 and located between the first signal line 310 and the second signal line 320. One of two connecting lines 332 that are located on either side of the same power supply block 331 in the second direction Y and connected to the power supply block 331 is a first connecting line 332a and the other one is a second connecting line 332b. The first connecting line 332a is disposed as extending through between the first connection portion 340 and the second signal line 320, and the second connecting line 332b is disposed as extending through between the second connection portion 350 and the first signal line 310. When the first signal line 310 is a first data line and the first data line is configured to transmit a data signal to a pixel circuit, the first connection portion 340 may be configured, for example, to connect the first signal line 310 and a pixel circuit driven by the first signal line 310. Similarly, when the second signal line 320 is a second data line and the second data line is configured to transmit a data signal to a pixel circuit, the second connection portion 350 may be configured to connect the second signal line 320 and a pixel circuit driven by the second signal line 320.

In these embodiments, the second conductive layer 03 includes the first connection portion 340 and the second connection portion 350, where the first connection portion 340 is connected to the first signal line 310 and located between the first signal line 310 and the second signal line 320, i.e., there is a first gap between the first connection portion 340 and the second signal line 320; and the second connection portion 350 is connected to the second signal line 320 and located between the first signal line 310 and the second signal line 320, i.e. there is a second gap between the first connection portion 340 and the first signal line 310. Since the first connection portion 340 is connected to the first signal line 310, the first gap is provided closer to the second signal line 320, and similarly, the second gap is provided closer to the first signal line 310. The first connecting line 332a and the second connecting line 332b are disposed on two sides of the same power supply block 331. The first connecting line 332a is disposed as extending through between the first connection portion 340 and the second signal line 320, i.e., the first connecting line 332a extends through the first gap; and the second connecting line 332b is disposed as extending through between the second connection portion 350 and the second signal line 320, i.e., the second connecting line 332b extends through the second gap, so that the insulation between the second power line 330 and the first signal line 310 and the second signal line 320 can be better ensured.

Various arrangements of the connection positions of the first and second connecting lines 332a, 332b and the power supply block 331 are provided. For example, the first connecting line 332a and the second connecting line 332b may be connected to the same side of the power supply block 331 in the first direction X.

In some other embodiments, the first connecting line 332a is connected to a side of the power supply block 331 facing toward the second signal line 320, and the second connecting line 332b is connected to a side of the power supply block 331 facing toward the first signal line 310.

In these embodiments, on the one hand, when the first connecting line 332a is located on the side of the power supply block 331 facing toward the second signal line 320, the first connecting line 332a may pass between the second signal line 320 and the first connection portion 340 along a relatively straight extension path, so that the shape of the first connecting line 332a can be simplified. Similarly, the second connecting line 332b is connected to the side of the power supply block 331 facing toward the first signal line 310, so that the shape of the second connecting line 332b can also be simplified, facilitating the preparation of the first connecting line 332a and the second connecting line 332b. On the other hand, the first connecting line 332a and the second connecting line 332b are connected to two sides of a diagonal of the power supply block 331, and the first connecting line 332a and the second connecting line 332b are symmetrically disposed relative to the power supply block 331, so that the problem of poor flatness of the pixel electrode 510 can be better alleviated.

In some embodiments, as shown in FIGS. 1 to 5, a plurality of second power lines 330 are spaced apart in the first direction X, and the power supply block 331 for at least one of the second power lines 330 includes a functional block 331a and an auxiliary block 331b. In one embodiment, an orthographic projection of the functional block 331a in the thickness direction Z at least partially overlaps the orthographic projection of the pixel electrode 510 in the thickness direction Z, and the distribution area and position of the functional block 331a will indirectly affect the flatness of the pixel electrode 510, i.e., the functional block 331a has a function of adjusting the flatness of the pixel electrode 510. The auxiliary block 331b is configured to assist in expanding the distribution area of the power supply block 331 to expand the distribution area of the second power line 330 and reduce the resistance of the second power line 330. The connecting line 332 of the second power line 330 further includes a third connecting line 332c. The auxiliary block 331b and the functional block 331a are spaced apart in the second direction Y and are connected to each other by the third connecting line 332c. The third connecting line 332c may be located closer to the second signal line 320 of the first signal line 310 and the second signal line 320; in one embodiment, the third connecting line 332c may be located closer to the first signal line 310 of the first signal line 310 and the second signal line 320.

One power supply block 331 may include one or more functional blocks 331a, and/or one power supply block 331 may include one or more auxiliary blocks 331b. If the auxiliary block 331b and the functional block 331a of the one power supply block 331 need to be connected through a plurality of third connecting lines 332c, the plurality of third connecting lines 332c may be located on the same side. For example, the plurality of third connecting lines 332c are all closer to the first signal line 310 than the second signal line 320. In one embodiment, the plurality of third connecting lines 332c are all closer to the second signal line 320 than the first signal line 310. In addition, the plurality of third connecting lines 332c may be located on different sides. For example, some of the third connecting lines 332c are closer to the first signal line 310 and the rest of the third connecting lines 332c are closer to the second signal line 320.

The second conductive layer 03 may further include a first via hole portion 360 provided between the auxiliary block 331b and the functional block 331a. The array substrate further includes a third conductive layer 04 and the fourth conductive layer 05 as described above. The third conductive layer 04 and the fourth conductive layer 05 are disposed on two sides of the second conductive layer 03 respectively, i.e., the third conductive layer 04 is located on the side of the second conductive layer 03 facing toward the substrate 01, and the fourth conductive layer 05 is located on the side of the second conductive layer 03 facing away from the substrate 01. The third conductive layer 04 includes a third signal line 410, and at least one pixel electrode 510 of the fourth conductive layer 05 is connected to the third signal line 410 through the first via hole portion 360.

The third signal line 410 is provided in various configurations. For example, a transistor in a pixel circuit of the array substrate includes a semiconductor portion, a gate, a source and a drain, and the third signal line 410 may be one of the source and the drain. In one embodiment, the third signal line 410 is a bridging line for connecting the pixel electrode 510 to the source or the drain. In some embodiments, the transistor in the pixel circuit is a thin film transistor (TFT).

Various arrangements of the relative positions of the third conductive layer 04 and the first conductive layer 02 are provided. The third conductive layer 04 may be located on the side of the first conductive layer 02 facing toward the substrate 01; in one embodiment, the third conductive layer 04 may be located between the first conductive layer 02 and the second conductive layer 03; in one embodiment, the third conductive layer 04 and the first conductive layer 02 are used as one piece.

In these embodiments, the power supply block 331 is divided into the auxiliary block 331b and the functional block 331a. The auxiliary block 331b and the functional block 331a are connected to each other by the third connecting line 332c. The first via hole portion 360 is provided between the auxiliary block 331b and the functional block 331a. That is, the power supply block 331 has the functional block 331a and the auxiliary block 331b, enabling the yielding of the first via hole portion 360, and enabling the pixel electrode 510 to be connected to the third signal line 410 through the first via hole portion 360.

The second power line 330 may be provided in various configurations. For example, a plurality of second power lines 330 spaced side by side in the first direction X may have the same shape and may be arranged in the same way.

In some other embodiments, the plurality of second power lines 330 include a first sub-power line 330a and a second sub-power line 330b. In some embodiments, the first sub-power line 330a and the second sub-power line 330b are adjacent to each other in the first direction X.

For example, as shown in FIG. 5, two adjacent second power lines 330 in the first direction X have different shapes. For example, one of the two adjacent second power lines 330 in the first direction X is a first sub-power line 330a and the other one is a second sub-power line 330b; and the first sub-power line 330a includes the functional block 331a as described above and includes no auxiliary block 331b, and the second sub-power line 330b includes the functional block 331a and the auxiliary block 331b as described above. That is, from the two adjacent second power lines 330, the power supply block 331 of one is provided integrally, and the power supply block 331 of the other one has the functional block 331a and the auxiliary block 331b.

In some embodiments, in the first sub-power line 330a that includes no auxiliary block 331b, a second via hole portion 370 is provided between the power supply block 331 and the first connection portion 340, and/or a second via hole portion 370 is provided between the power supply block 331 and the second connection portion 350. The pixel electrode 510 is connected to the third signal line 410 through the second via hole portion 370. The second via hole portion 370 is located in the second conductive layer 03. As can be seen from the above, both the first via hole portion 360 and the second via hole portion 370 are configured to connect the pixel electrode 510 to the third signal line 410. The differences between the two lie in that the first via hole portion 360 and the second via hole portion 370 are provided at different positions, the first via hole portion 360 is provided in a column where the second sub-power line 330b is located, and the second via hole portion 370 is provided in a column where the first sub-power line 330a is located. Therefore, the first via hole portion 360 is configured to connect the pixel electrode 510 in the column where the second sub-power line 330b is located to the third signal line 410, and the second via hole portion 370 is configured to connect the pixel electrode 510 in the column where the first sub-power line 330a is located to the third signal line 410. In these embodiments, the two adjacent second power lines 330 in the first direction X have different shapes, and the pixel electrodes 510 corresponding thereto are connected to the third signal line 410 at different positions. With continued reference to examples shown in FIGS. 3 and 5, the pixel electrode 510 includes a first pixel electrode 510a and a second pixel electrode 510b adjacent to each other in the first direction X. An orthographic projection of the first pixel electrode 510a in the thickness direction Z at least partially overlaps an orthographic projection of the power supply block 331 of the first sub-power line 330a in the thickness direction Z, and an orthographic projection of the second pixel electrode 510b at least partially overlaps an orthographic projection of the functional block 331a of the second sub-power line 330b in the thickness direction Z. The first pixel electrode 510a and the second pixel electrode 510b are connected to different third signal lines 410. The first pixel electrode 510a is connected to the third signal line 410 through the second via hole portion 370, and the second pixel electrode 510b is connected to the third signal line 410 through the first via hole portion 360. The reasonable arrangement of the first connection portion 340, the second connection portion 350, the first via hole portion 360, the second via hole portion 370, the first sub-power line 330a, and the second sub-power line 330b is conducive to the implementation of various functions.

In the above embodiments, the plurality of second power lines 330 may include the first sub-power line 330a and the second sub-power line 330b. For example, the plurality of second power lines 330 may include the first sub-power line 330a and the second sub-power line 330b disposed alternately. In yet some other embodiments, the plurality of second power lines 330 may include one of the first sub-power line 330a and the second sub-power line 330b. For example, the second power line 330 may include only the first sub-power line 330a. In still some other embodiments, the second power line 330 may include only the second sub-power line 330b.

In one embodiment, the area of an orthographic projection of a power supply block 331 of the first sub-power line 330a in the thickness direction Z is larger than the area of an orthographic projection of a functional block 331a of the second sub-power line 330b in the thickness direction Z, and the area of an orthographic projection of a first pixel electrode 510 in the thickness direction Z is larger than the area of an orthographic projection of a second pixel electrode 510 in the thickness direction Z. That is, for pixel electrodes 510 in different sizes, the power supply blocks 331 of the first sub-power line 330a and the second sub-power line 330b are designed with different sizes, so that the problem of poor flatness of the first pixel electrode 510 and the second pixel electrode 510 can be alleviated better.

In some embodiments, an orthographic projection of the first power line 210 on the substrate 01 at least partially overlaps the orthographic projection of the second power line 330 on the substrate 01. In this way, it can be ensured that a distance between each first power line 210 and each second power line 330 is close enough to facilitate the connection between the first power line 210 and the second power line 330. In any of the above embodiments, various arrangements of the shapes of the first connecting line 332a and the second connecting line 332b are provided, as long as both the first connecting line 332a and the second connecting line 332b can be connected to the adjacent power supply block 331, respectively.

For example, in the first sub-power line 330a, the first connecting line 332a and the second connecting line 332b may extend along a straight path. The first connecting line 332a is located on a side of the power supply block 331 of the first sub-power line 330a close to the second signal line 320, and the second connecting line 332b is located on a side of the power supply block 331 of the first sub-power line 330a close to the first signal line 310. Since the first connecting line 332a and the second connecting line 332b extend along the straight path, the shapes of the first connecting line 332a and the second connecting line 332b may be simplified, facilitating the preparation of the first connecting line 332a and the second connecting line 332b.

In one embodiment, a plurality of second via hole portions 370 are provided. The second via hole portions 370 may be located between the power supply blocks 331 of the first sub-power line 330a and the first connection portion 340 and/or the second connection portion 350. In one embodiment, the number of the second via hole portions 370 is the same as the number of the power supply blocks 331 in the first sub-power line 330a. A second via hole portion 370 is provided on one side of one of the power supply blocks 331 in the second direction Y to improve the connection area between the first power line 210 and the first sub-power line 330a.

In one embodiment, various arrangements of the shape of the third connecting line 332c are provided in the second sub-power line 330b. For example, the third connecting line 332c may extend along a straight path, so that the shape of the third connecting line 332c is simplified.

In one embodiment, the area of the functional block 331a and the auxiliary block 331b may be the same or different. For example, the area of the orthographic projection of the functional block 331a in the thickness direction Z is larger than the area of the orthographic projection of the auxiliary block 331b in the thickness direction Z. The functional block 331a overlaps the pixel electrode 510, and the functional block 331a has a large area, which can better alleviate the problem of poor flatness of the pixel electrode 510.

In one embodiment, the first connecting line 332a and/or the second connecting line 332b are/is configured to connect the functional block 331a of one of two adjacent power supply blocks 331 to the auxiliary block 331b of the other one of the two adjacent power supply blocks. Various arrangements of the shapes of the first connecting line 332a and the second connecting line 332b are provided. For example, the auxiliary block 331b is aligned with an edge of the power supply block 331 facing toward the second signal line 320 in the second direction Y, the first connecting line 332a may extend linearly to connect the functional block 331a of one of the two adjacent power supply blocks 331 to the auxiliary block 331b of the other one of the two adjacent power supply blocks, so that the shape of the first connecting line 332a can be simplified. In one embodiment, when the auxiliary block 331b and an edge of the power supply block 331 facing toward the first signal line 310 are arranged in a staggered manner in the second direction Y, the second connecting line 332b extends along a bend path to connect the functional block 331a of one of the two adjacent power supply blocks 331 to the auxiliary block 331b of the other one of the two adjacent power supply blocks.

In one embodiment, in the second sub-power line 330b, the first connecting line 332a and the third connecting line 332c are aligned in the second direction Y, so that the shape of the connecting line 332 is simplified.

An embodiment of a second aspect of the present application further provides a display panel including an array substrate of any one of the above-described embodiments of the first aspect. Since the display panel according to the embodiment of the second aspect of the present application includes the array substrate described above, the display panel according to the embodiment of the second aspect of the present application has the same beneficial effects as the above-described array substrate, which will not be repeated herein.

The display panel according to the embodiment of the present application may be at least one of an organic light-emitting diode display panel, a liquid crystal display panel, and a micro light-emitting diode display panel.

An embodiment of a third aspect of the present application further provides a display device, including a display panel of any one of the above-described embodiments of the first aspect. Since the display device according to the embodiment of the third aspect of the present application includes the display panel according to any one of the above-described embodiments of the first aspect, the display device according to the embodiment of the third aspect of the present application has the beneficial effects as the display panel according to any one of the above-described embodiments of the second aspect, which will not be repeated herein.

The display device in the embodiment of the present application includes, but is not limited to devices having a display function, such as a cell phone, a personal digital assistant (PDA), a tablet computer, an e-book, a television, an access control, a smart fixed-line telephone, or a control console.

1. An array substrate, comprising:
a substrate;
a first conductive layer located on one side of the substrate, the first conductive layer comprising a first power line; and
a second conductive layer located on a side of the first conductive layer facing away from the substrate, the second conductive layer comprising at least one first signal line and at least one second signal line spaced apart in a first direction and at least one second power line between the first signal line and the second signal line,
wherein the first power line, the first signal line, the second signal line and the second power line are each formed as extending in a second direction, and the first power line and the second power line are connected through via holes.

2. The array substrate according to claim 1, wherein the second power line comprises a plurality of power supply blocks spaced apart in the second direction and a connecting line connected between every two adjacent power supply blocks, wherein a width of the connecting line in the first direction is less than a width of one of the power supply blocks in the first direction.

3. The array substrate according to claim 2, wherein the second conductive layer further comprises:
a first connection portion connected to the first signal line and located between the first signal line and the second signal line; and
a second connection portion connected to the second signal line and located between the first signal line and the second signal line;
wherein one of the two connecting lines that are located on either side of the same power supply block in the second direction and connected to the power supply block is a first connecting line and the other one is a second connecting line, the first connecting line being disposed as extending through between the first connection portion and the second signal line, and the second connecting line being disposed as extending through between the second connection portion and the first signal line.

4. The array substrate according to claim 3, wherein the first connecting line is connected to a side of the power supply block facing toward the second signal line, and the second connecting line is connected to a side of the power supply block facing toward the first signal line.

5. The array substrate according to claim 2, wherein
a plurality of second power lines of the at least one second signal line are spaced apart in the first direction, the power supply block for at least one of the second power lines comprises a functional block and an auxiliary block, and the connecting line of the second power line further comprises a third connecting line, the auxiliary block and the functional block being spaced apart in the second direction and connected to each other by the third connecting line.

6. The array substrate according to claim 5, wherein a first via hole portion is provided between the auxiliary block and the functional block; and
the array substrate further comprises a third conductive layer and a fourth conductive layer, wherein the third conductive layer and the fourth conductive layer are disposed on two sides of the second conductive layer, respectively, the third conductive layer comprises a third signal line, and the fourth conductive layer comprises a pixel electrode connected to the third signal line through the first via hole portion.

7. The array substrate according to claim 5, wherein the plurality of second power lines comprise a first sub-power line and a second sub-power line, the first sub-power line comprising the functional block and comprising no auxiliary block, and the second sub-power line comprising the functional block and the auxiliary block.

8. The array substrate according to claim 7, wherein a second via hole portion is provided between the power supply block for the first sub-power line and a first connection portion, and a second via hole portion is provided between the power supply block of the first sub-power line and the second connection portion; and
a pixel electrode is connected to a third signal line through the second via hole portion.

9. The array substrate according to claim 7, wherein the first sub-power line and the second sub-power line are adjacent to each other in the first direction.

10. The array substrate according to claim 2, wherein the array substrate further comprises:
a fourth conductive layer located on a side of the second conductive layer facing away from the substrate, the fourth conductive layer comprising a pixel electrode, and an orthographic projection of the pixel electrode in a thickness direction of the array substrate at least partially overlapping an orthographic projection of the second power line in the thickness direction.

11. The array substrate according to claim 10, wherein an orthographic projection of one of the power supply blocks in the thickness direction at least partially overlaps an orthographic projection of the pixel electrode in the thickness direction.

12. The array substrate according to claim 10, wherein an orthographic projection of the power supply block in the thickness direction has central symmetry about a center point of an orthographic projection of the pixel electrode in the thickness direction.

13. The array substrate according to claim 10, wherein an orthographic projection of the power supply block in the thickness direction lies within an orthographic projection of the pixel electrode in the thickness direction.

14. The array substrate according to claim 10, wherein at least two pixel electrodes have different areas, at least two of the power supply blocks have different areas, and the area of each of the power supply blocks is in positive correlation with the area of the pixel electrodes corresponding to the power supply block.

15. The array substrate according to claim 1, wherein an orthographic projection of the first power line on the substrate at least partially overlaps an orthographic projection of the second power line on the substrate.

16. The array substrate according to claim 1, wherein
the array substrate further comprises a plurality of pixel circuits disposed on one side of the substrate, the plurality of pixel circuits being arranged in a column in the second direction; and
the first signal line is a first data line, and the second signal line is a second data line, the first data line and the second data line being used to provide data signals to the plurality of pixel circuits arranged in the same column in the second direction.

17. The array substrate according to claim 16, wherein the first data line provides a data signal to one of two adjacent pixel circuits in the second direction, and the second data line provides a data signal to the other one of the two adjacent pixel circuits.

18. A display panel, comprising an array substrate according to claim 1.
